(19) United States
(12) Patent Application Publication
(10) Pub. No.: US 2026/0223719 A1
(43) Pub. Date: Jul. 30, 2026

(54) SEMICONDUCTOR DEVICE

(71) Applicant: SUMITOMO ELECTRIC DEVICE INNOVATIONS, INC., Kanagawa (JP)

(72) Inventor: Seiya TAKASHIMA, Osaka (JP)

(21) Appl. No.: 19/421,474

(22) Filed: Dec. 16, 2025

(30) Foreign Application Priority Data
Jan. 24, 2025 (JP) 2025-010553

(51) Int. Cl. H10W 72/50; H10D 80/20

(52) U.S. Cl. CPC H10W 72/5445; H10D 80/251

(57) ABSTRACT

A semiconductor device includes a semiconductor chip including an amplifier, an input pad of the amplifier provided on an upper surface of the semiconductor chip, and an output pad of the amplifier provided on the upper surface of the semiconductor chip, input bonding wires each having a first end bonded to the input pad, and output bonding wires each having a first end bonded to the output pad. The input bonding wires include a first input bonding wire that is the thickest among the input bonding wires. A width of the output pad in a region to which at least one of first output bonding wires among the output bonding wires is bonded is larger than a largest width of the input pad in regions to which the input bonding wires are bonded. The first output bonding wires are thicker than the first input bonding wire.

### CROSS REFERENCE TO RELATED APPLICATIONS

This application is based on and claims priority to Japanese Patent Application No. 2025-010553 filed on January 24, 2025, and the entire contents of which are incorporated herein by reference.

### TECHNICAL FIELD

The present disclosure relates to a semiconductor device.

### BACKGROUND

Making the outermost bonding wire thicker, among the bonding wires connected to a drain pad of a transistor chip, is known (for example, Patent Literature: Japanese Unexamined Patent Application Publication No. 2017-59650).

### SUMMARY

A semiconductor device according to an embodiment of the present disclosure includes a semiconductor chip including an amplifier, an input pad of the amplifier provided on an upper surface of the semiconductor chip, and an output pad of the amplifier provided on the upper surface of the semiconductor chip, input bonding wires each having a first end bonded to the input pad, and output bonding wires each having a first end bonded to the output pad. The input bonding wires include a first input bonding wire that is the thickest among the input bonding wires. A width of the output pad in a region to which at least one of first output bonding wires among the output bonding wires is bonded is larger than a largest width of the input pad in regions to which the input bonding wires are bonded. The first output bonding wires are thicker than the first input bonding wire.

### BRIEF DESCRIPTION OF THE DRAWINGS

FIG. 1 is a circuit diagram of an amplifying circuit used in a first embodiment;

FIG. 2 is a plan view of a semiconductor device according to the first embodiment;

FIG. 3 is an A-A cross-sectional view of FIG. 2;

FIG. 4 is a plan view of a semiconductor chip in the first embodiment;

FIG. 5 is an A-A cross-sectional view of FIG. 4;

FIG. 6 is a B-B cross-sectional view of FIG. 4;

FIG. 7 is another B-B cross-sectional view of FIG. 4;

FIG. 8 is a plan view around a semiconductor chip of a semiconductor device according to a first comparative embodiment;

FIG. 9 is a plan view around a semiconductor chip of a semiconductor device according to a second comparative embodiment;

FIG. 10 is a plan view around a semiconductor chip of the semiconductor device according to the first embodiment;

FIG. 11 is a plan view around a semiconductor chip of a semiconductor device according to a first modification of the first embodiment; and

FIG. 12 is a plan view around a semiconductor chip of a semiconductor device according to a second modification of the first embodiment.

### DETAILED DESCRIPTION

Because a large current flows through the outermost bonding wire, the outermost bonding wire is made thick, so that the fusing of the bonding wire can be reduced. However, making the bonding wire thicker increases the pad size and enlarges the semiconductor chip.

It is desired to provide a semiconductor device that can reduce the size of a semiconductor chip.

According to the present disclosure, it is possible to provide a semiconductor device that can reduce the size of a semiconductor chip.

### Description of Embodiments of Present Disclosure

First, embodiments of the present disclosure will be listed and described.

(1) A semiconductor device according to an embodiment of the present disclosure includes a semiconductor chip including an amplifier, an input pad of the amplifier provided on an upper surface of the semiconductor chip, and an output pad of the amplifier provided on the upper surface of the semiconductor chip, input bonding wires each having a first end bonded to the input pad, and output bonding wires each having a first end bonded to the output pad. The input bonding wires include a first input bonding wire that is the thickest among the input bonding wires. A width of the output pad in a region to which at least one of first output bonding wires among the output bonding wires is bonded is larger than a largest width of the input pad in regions to which the input bonding wires are bonded, the first output bonding wires being thicker than the first input bonding wire. This prevents the first output bonding wire from being fused and the size of the semiconductor chip can be reduced.

(2) In the above (1), the number of the first output bonding wires may be more than half of the number of the output bonding wires. This prevents many first output bonding wires from being fused.

(3) In the above (1), all of the output bonding wires may be thicker than the first input bonding wire. This prevents the output bonding wire from being fused.

(4) In any one of the above (1) to (3), in all regions to which the first output bonding wires are bonded, the width of the output pad may be larger than the largest width. This can reduce the size of the semiconductor chip.

(5) In any one of the above (1) to (4), the semiconductor device may further include an output terminal electrically connected to the output pad. The at least one of the first output bonding wires is provided in an output path electrically connecting the output pad to the output terminal. This prevents the output bonding wire provided in the output path from being fused.

(6) In the above (5), all of the output bonding wires provided in the output path may be thicker than the first input bonding wire. This prevents the output bonding wire provided in the output path from being fused.

(7) In the above (5) or (6), the semiconductor device may further include second output bonding wires connected in series with the at least one of the output bonding wires in the output path. At least one of the second output bonding wires may be thicker than the first input bonding wire. This prevents the second output bonding wire from being fused.

(8) In the above (7), the semiconductor device may further include a base on which the semiconductor chip is mounted, and a first passive component mounted on the base. The first output bonding wires may each have a second end bonded to the first passive component. The second output bonding wires may each have a first end bonded to the first passive component and a second end bonded to the output terminal. This prevents the second output bonding wire from being fused.

(9) In any one of the above (1) to (8), the semiconductor device may further include a base on which the semiconductor chip is mounted, a second passive component mounted on the base, an input terminal electrically connected to the input pad, and second input bonding wires each having a first end bonded to the second passive component and a second end bonded to the input terminal. The first input bonding wire may have a second end bonded to the second passive component. At least one of the output bonding wires may be thicker than any of the second input bonding wires. This prevents the first output bonding wire from being fused.

(10) In any one of the above (1) to (9), the amplifier may include a transistor having an input electrode and an output electrode. The input pad may be a portion of a metal layer electrically connected to the input electrode, and the portion may be located outside an active region of the transistor and exposed from a protective film covering the transistor. The output pad may be a portion of a metal layer electrically connected to the output electrode, and the portion may be located outside the active region and exposed from the protective film. This can reduce the size of the semiconductor chip.

(11) In any one of the above (1) to (10), the upper surface of the semiconductor chip may have a first side and a second side opposite to each other. A plurality of regions where the input bonding wires are bonded to the input pad may be provided along the first side. A plurality of regions where the output bonding wires are bonded to the output pad may be provided along the second side. The largest width may be a largest width of the input pad in a direction perpendicular to an extending direction of the first side. The width of the output pad may be a width of the output pad in a direction perpendicular to an extending direction of the second side. This can reduce the size the semiconductor chip.

### Details of Embodiments of Present Disclosure

Specific examples of a semiconductor device according to an embodiment of the present disclosure will be described below with reference to the drawings. The present disclosure is not limited to these examples, but is defined by the scope of the claims, and is intended to include all modifications within the meaning and scope equivalent to the scope of the claims.

### First Embodiment

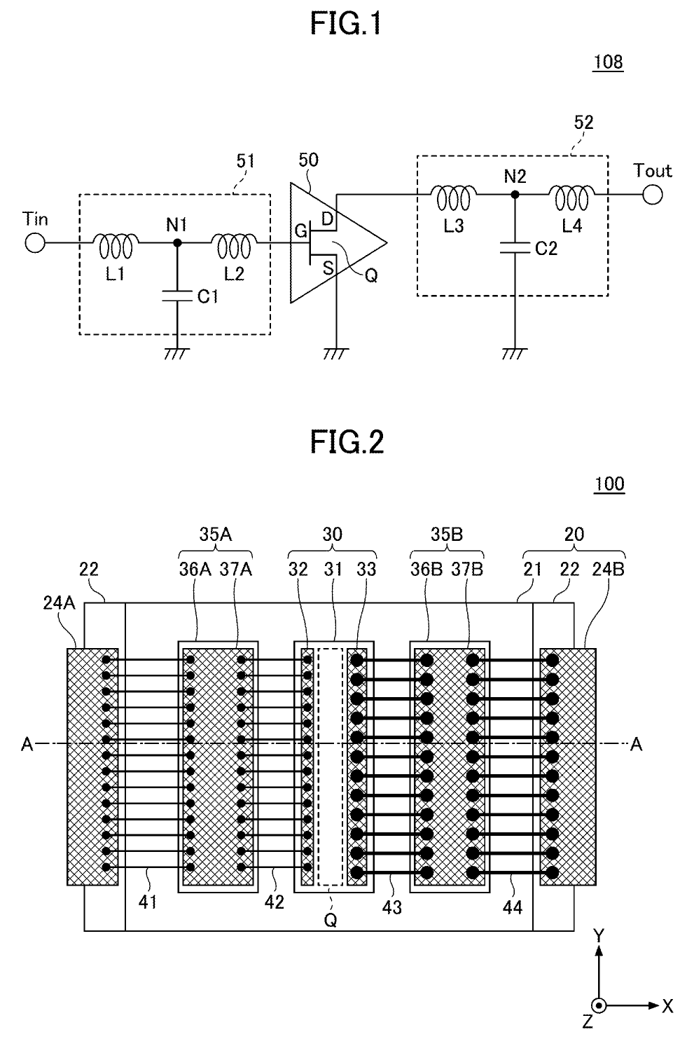

FIG. 1 is a circuit diagram of an amplifying circuit used in a first embodiment. As illustrated in FIG. 1, an amplifying circuit 108 according to the first embodiment includes an amplifier 50 and matching circuits 51 and 52.

The amplifier 50 includes a transistor Q. The transistor Q is, for example, a field effect transistor (FET), and includes a source S, a drain D, and a gate G. The source S is electrically connected to a reference potential terminal such as a ground terminal and is short-circuited. The gate G is electrically connected to an input terminal Tin via the matching circuit 51.

The transistor Q is, for example, a gallium nitride high-electron-mobility transistor (GaN HEMT) or a laterally diffused metal oxide semiconductor (LDMOS).

The matching circuit 51 matches the impedance seen from the input terminal Tin toward the matching circuit 51 with the impedance seen from the matching circuit 51 toward the gate G. The amplifier 50 amplifies a high-frequency signal input to the gate G and outputs the amplified high-frequency signal to the drain D. The matching circuit 52 matches the impedance seen from the drain D toward the matching circuit 52 with the impedance seen from the matching circuit 52 toward an output terminal Tout.

The matching circuit 51 includes inductors L1 and L2, and a capacitor C1. The inductors L1 and L2 are connected in series between the input terminal Tin and the gate G. The capacitor C1 is shunt-connected to a node N1 between the inductor L1 and the inductor L2. The matching circuit 52 includes inductors L3 and L4, and a capacitor C2. The inductors L3 and L4 are connected in series between the drain D and the output terminal Tout. The capacitor C2 is shunt-connected to a node N2 between the inductor L3 and the inductor L4.

When the amplifying circuit 108 is used in a power amplifier for a base station for mobile communication, the center frequency of the operating band is, for example, 0.5 GHz or greater and 20 GHz or less.

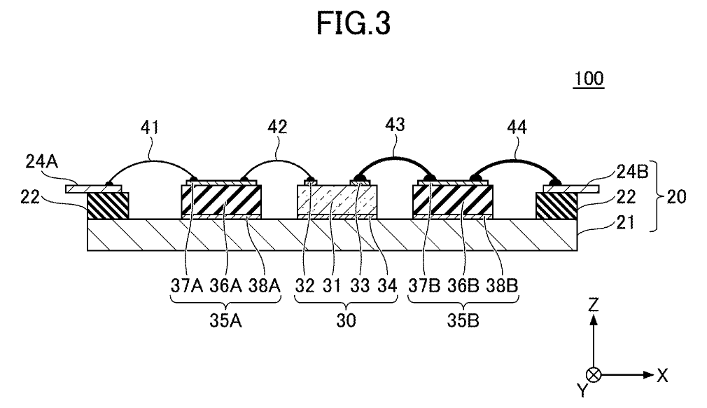

FIG. 2 is a plan view of a semiconductor device according to the first embodiment. FIG. 3 is an A-A cross-sectional view of FIG. 2. A thickness direction of a base 21 is defined as a Z direction, a direction from an input terminal 24A to an output terminal 24B is defined as an X direction, and a direction orthogonal to the X direction and the Z direction is defined as a Y direction. A semiconductor device 100 of the first embodiment corresponds to the amplifying circuit 108 of FIG. 1.

As illustrated in FIGS. 2 and 3, the semiconductor device 100 according to the first embodiment includes a package 20, a semiconductor chip 30, and passive components 35A and 35B.

The package 20 includes the base 21, a dielectric layer 22, the input terminal 24A, and the output terminal 24B. At least a +Z surface of the base 21 is a conductor. The base 21 may be a metal plate in which, for example, a copper layer, a molybdenum layer, and a copper layer are stacked. The base 21 functions as a reference potential terminal to which a reference potential such as a ground potential is supplied.

The semiconductor chip 30 and the passive components 35A and 35B are mounted on the base 21 with, for example, a conductive bonding layer interposed therebetween. The dielectric layer 22 is provided on the base 21 so as to sandwich the semiconductor chip 30 and the passive components 35A and 35B in the X direction. The dielectric layer 22 is an insulating layer made of, for example, ceramics or resin. The dielectric layer 22 may be a frame body surrounding the semiconductor chip 30 and the passive components 35A and 35B. A cover for sealing the semiconductor chip 30 may be bonded onto the frame body. The input terminal 24A and the output terminal 24B are provided on the dielectric layer 22. The input terminal 24A and the output terminal 24B are, for example, metal layers, such as copper layers or gold layers. The input terminal 24A and the output terminal 24B correspond to the input terminal Tin and the output terminal Tout, respectively.

The semiconductor chip 30 includes a semiconductor substrate 31, an input pad 32, an output pad 33, an electrode 34, and the transistor Q. The input pad 32 and the output pad 33 are provided on an upper surface of the semiconductor substrate 31. The electrode 34 is provided on a lower surface of the semiconductor substrate 31. The input pad 32, the output pad 33, and the electrode 34 are electrically connected to the gate G, the drain D, and the source S of the transistor Q, respectively. The input pad 32 is electrically connected to the input terminal 24A via the passive component 35A. The output pad 33 is electrically connected to the output terminal 24B via the passive component 35B. When the transistor Q is a GaN HEMT, the semiconductor substrate 31 is, for example, a silicon carbide substrate or a sapphire substrate. When the transistor Q is an LDMOS, the semiconductor substrate 31 is, for example, a silicon substrate. The input pad 32, the output pad 33, and the electrode 34 are metal layers, such as gold layers or copper layers.

The passive component 35A includes a dielectric substrate 36A, and electrodes 37A and 38A. The passive component 35B includes a dielectric substrate 36B, and electrodes 37B and 38B. The electrodes 37A and 37B are provided on upper surfaces of the dielectric substrates 36A and 36B, respectively. The electrodes 38A and 38B are provided on lower surfaces of the dielectric substrates 36A and 36B, respectively. The dielectric substrates 36A and 36B are, for example, alumina substrates or barium titanate substrates. The electrodes 37A, 37B, 38A, and 38B are metal layers, such as gold layers or copper layers. The dielectric substrate 36A and the electrodes 37A and 38A sandwiching the dielectric substrate 36A correspond to the capacitor C1. The dielectric substrate 36B and the electrodes 37B and 38B sandwiching the dielectric substrate 36B correspond to the capacitor C2. The passive component 35A may have a line pattern in addition to the capacitor C1, and the passive component 35B may have a line pattern in addition to the capacitor C2.

A bonding wire 41 electrically connects the input terminal Tin to the electrode 37A. A bonding wire 42 electrically connects the electrode 37A to the input pad 32. A bonding wire 43 electrically connects the output pad 33 to the electrode 37B. A bonding wire 44 electrically connects the electrode 37B to the output terminal 24B. The bonding wires 41 to 44 are thin metal wires, such as gold wires or aluminum wires. The bonding wires 41 to 44 correspond to the inductors L1, L2, L3, and L4, respectively. The bonding wires 43 and 44 are thicker than the bonding wires 41 and 42.

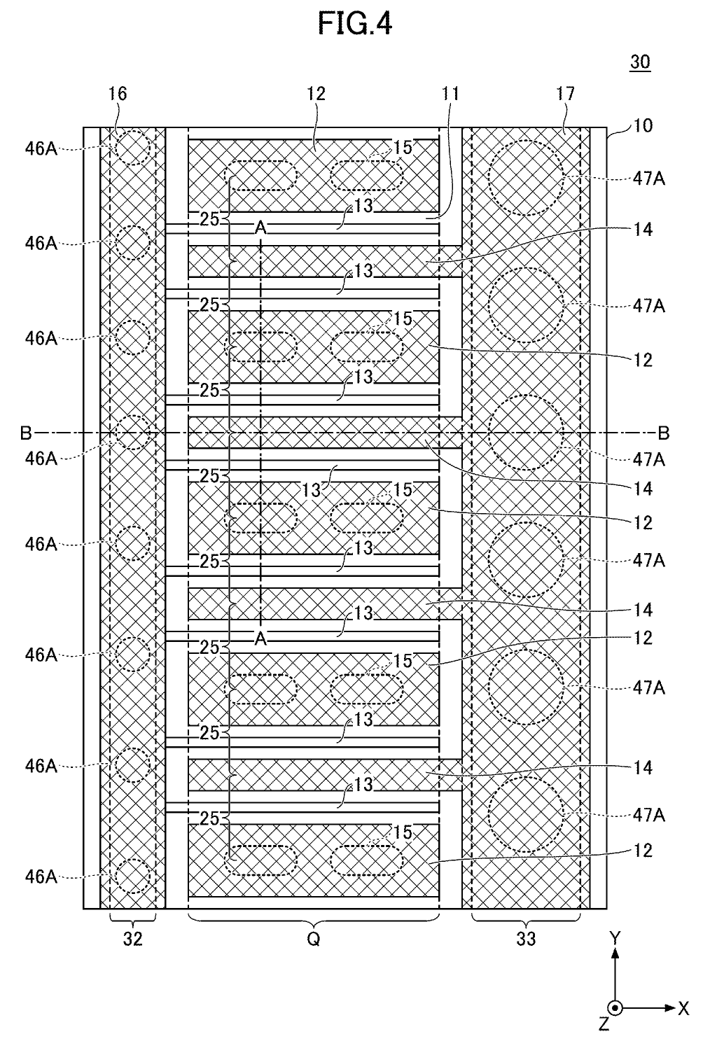

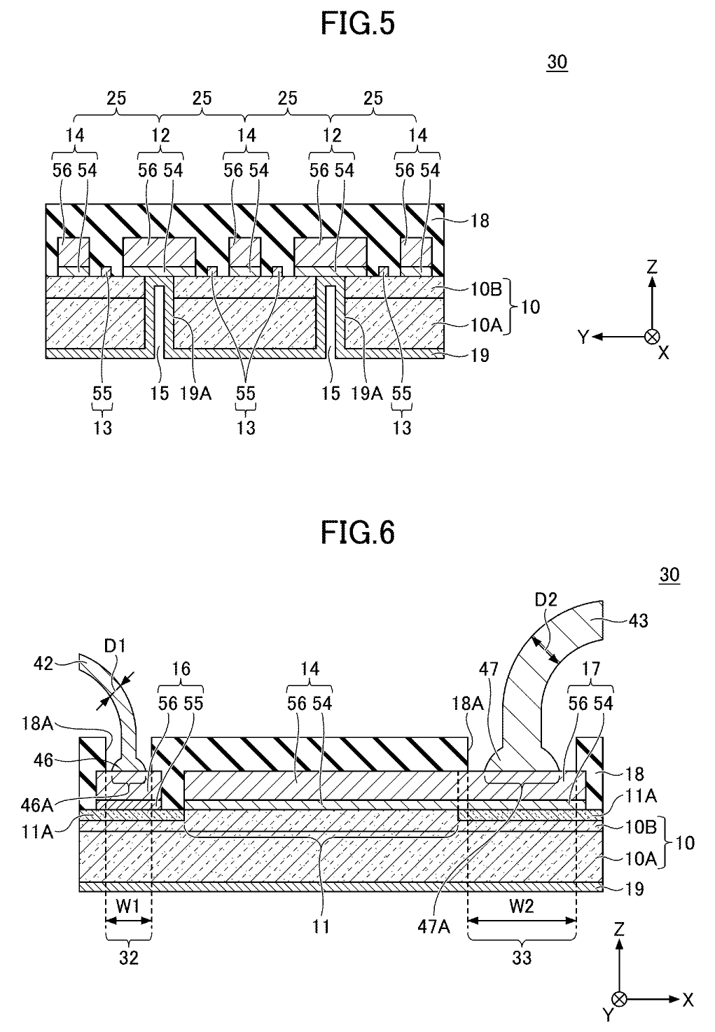

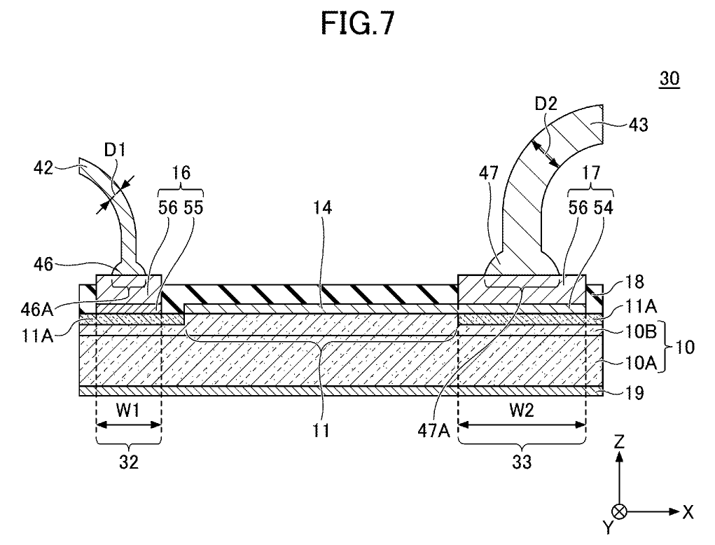

FIG. 4 is a plan view of a semiconductor chip in the first embodiment. FIG. 5 is an A-A cross-sectional view of FIG. 4. FIG. 6 is a B-B cross-sectional view of FIG. 4. FIG. 7 is another B-B cross-sectional view of FIG. 4. FIG. 4 is a plan view of a portion of the semiconductor chip 30. In FIGS. 4 to 7, a GaN HEMT is described as an example.

As illustrated in FIGS. 4 to 7, the semiconductor chip 30 includes a substrate 10, a unit FET 25, and metal layers 16 and 17. The substrate 10 includes a substrate 10A and a semiconductor layer 10B provided on the substrate 10A. In the semiconductor layer 10B, a region that has been inactivated by ion implantation or the like is an inactive region 11A, and a region that has not been inactivated is an active region 11. The active region 11 is provided with the transistor Q. The transistor Q includes a plurality of unit FETs 25.

The transistor Q includes a plurality of source electrodes 12, a plurality of gate electrodes 13, and a plurality of drain electrodes 14. The plurality of source electrodes 12, the plurality of gate electrodes 13, and the plurality of drain electrodes 14 each have a finger shape extending in the X direction. The plurality of source electrodes 12 and the plurality of drain electrodes 14 are alternately provided in the Y direction. One source electrode 12 and one drain electrode 14 sandwich one gate electrode 13 in the Y direction.

The metal layer 16 and the metal layer 17 sandwich the transistor Q in the X direction. The plurality of gate electrodes 13 are connected to the metal layer 16 at the end thereof in the -X direction. The plurality of drain electrodes 14 are connected to the metal layer 17 at the end thereof in the +X direction.

As illustrated in FIGS. 5 and 6, the source electrode 12, the drain electrode 14, and the metal layer 17 include an ohmic metal layer 54 provided on the substrate 10 in contact therewith and a wiring layer 56 provided on the ohmic metal layer 54 in contact therewith. The gate electrode 13 has a gate metal layer 55 provided on the substrate 10 in contact therewith. The metal layer 16 includes the gate metal layer 55 and the wiring layer 56 provided on the gate metal layer 55 in contact therewith.

As illustrated in FIGS. 5 to 7, each of the source electrode 12 and the drain electrode 14 need not include the wiring layer 56. In FIGS. 6 and 7, the metal layer 16 need not include the gate metal layer 55. The metal layer 17 need not include the ohmic metal layer 54.

As illustrated in FIGS. 5 and 6, a protective film 18 is provided on the substrate 10 so as to cover the unit FETs 25 and the metal layers 16 and 17. The protective film 18 is provided with openings 18A. Each of the openings 18A exposes a surface of the metal layer 16 or 17. The metal layers 16 and 17 exposed from the openings 18A correspond to the input pad 32 and the output pad 33, respectively. The input pad 32 and the output pad 33 are provided outside the active region 11.

As illustrated in FIG. 7, the protective film 18 need not cover the upper portion of the metal layer 16 or 17. Upper surfaces of the metal layers 16 and 17 are exposed from the protective film 18. The metal layers 16 and 17 correspond to the input pad 32 and the output pad 33, respectively. As illustrated in FIGS. 6 and 7, a width W2 of the output pad 33 in the X direction is larger than a width W1 of the input pad 32 in the X direction.

As illustrated in FIGS. 4 and 5, a via hole 15 penetrates the substrate 10. The via hole 15 overlaps the source electrode 12 when viewed from the Z direction and is connected to the source electrode 12. A metal layer 19 is provided on a rear surface of the substrate 10. A metal layer 19Ais provided on an inner surface of the via hole 15. Thus, the metal layer 19 is electrically connected to the source electrode 12 through the via hole 15, and is short-circuited. The metal layer 19 corresponds to the electrode 34. The planar shape of the via hole 15 may be an elliptical shape, an oval shape, a rounded square shape, or a circular shape.

A source potential (for example, a reference potential such as a ground potential) is supplied from the base 21 to the source electrode 12 through the metal layer 19 and the metal layer 19A in the via hole 15. A gate potential (for example, a high-frequency signal and a gate bias voltage) is supplied from the metal layer 16 to the gate electrode 13. A drain potential (for example, a drain bias voltage) is supplied from the metal layer 17 to the drain electrode 14. The high- frequency signal amplified in the transistor Q is output from the drain electrode 14 to the output pad 33.

The substrate 10A is, for example, a silicon carbide (SiC) substrate, a silicon (Si) substrate, a gallium nitride (GaN) substrate, or a sapphire (Al₂O₃) substrate. The semiconductor layer 10B includes a gallium nitride channel layer provided on the substrate 10A and an aluminum gallium nitride barrier layer provided on the channel layer.

The ohmic metal layer 54 is, for example, a titanium film and an aluminum film from the substrate 10. The gate metal layer 55 is, for example, a nickel film and a gold film from the substrate 10. The wiring layer 56 is a metal layer, such as a gold layer, a copper layer, or an aluminum layer. The protective film 18 is an insulating layer, and is an organic insulating layer, such as a polyimide layer or a benzocyclobutene (BCB) layer. The protective film 18 may include an inorganic insulator layer, such as a silicon oxide film or a silicon nitride film.

As illustrated in FIGS. 6 and 7, the first end of the bonding wire 42 is bonded to the input pad 32. The first end of the bonding wire 43 is bonded to the output pad 33. A bonding portion 46 of the bonding wire 42 to the input pad 32 is hemispherical and is larger than a diameter D1 of the bonding wire 42. A bonding portion 47 of the bonding wire 43 to the output pad 33 is hemispherical and is larger than a diameter D2 of the bonding wire 43. A region of the input pad 32 to which the bonding wire 42 is bonded is a region 46A. A region of the output pad 33 to which the bonding wire 43 is bonded is a region 47A. As illustrated in FIG. 4, the regions 46A are arranged in the Y direction, and the regions 47A are arranged in the Y direction.

### First Comparative Embodiment

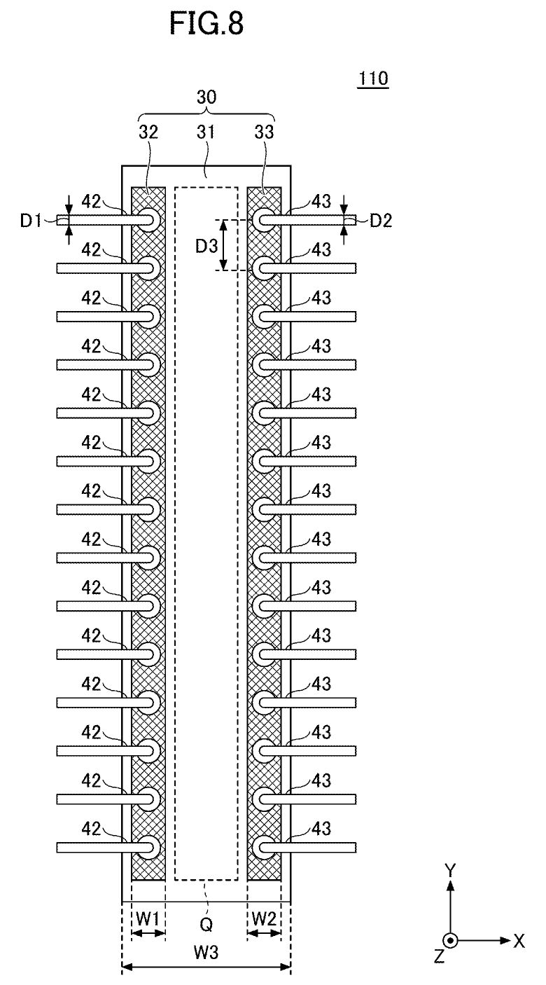

FIG. 8 is a plan view around the semiconductor chip 30 of a semiconductor device 110 according to a first comparative embodiment. In the semiconductor device 110 of the first comparative embodiment, the diameter D1 of the bonding wire 42 is equal to the diameter D2 of the bonding wire 43. The width W1 of the input pad 32 in the X direction is equal to the width W2 of the output pad 33 in the X direction. The widths W1 and W2 are determined according to the diameters D1 and D2. For example, when the diameters D1 and D2 are 25 μm, the widths W1 and W2 are 90 μm or more. A width W3 of the semiconductor chip 30 in the X direction is determined in consideration of the width of the transistor Q in the X direction and the widths W1 and W2.

In the amplifying circuit 108 having a large output, the bonding wire 43 is likely to be fused because the power of the output signal is large. As the output power increases, the current density in the bonding wire 43 increases. The bonding wire 43 generates heat due to conductor loss of the bonding wire 43. When the diameter D2 of the bonding wire 43 is small, heat is less likely to be conducted through the bonding wire 43. Thus, the temperature of the central portion of the bonding wire 43 in the longitudinal direction rises, and the bonding wire 43 is likely to be fused.

### Second Comparative Embodiment

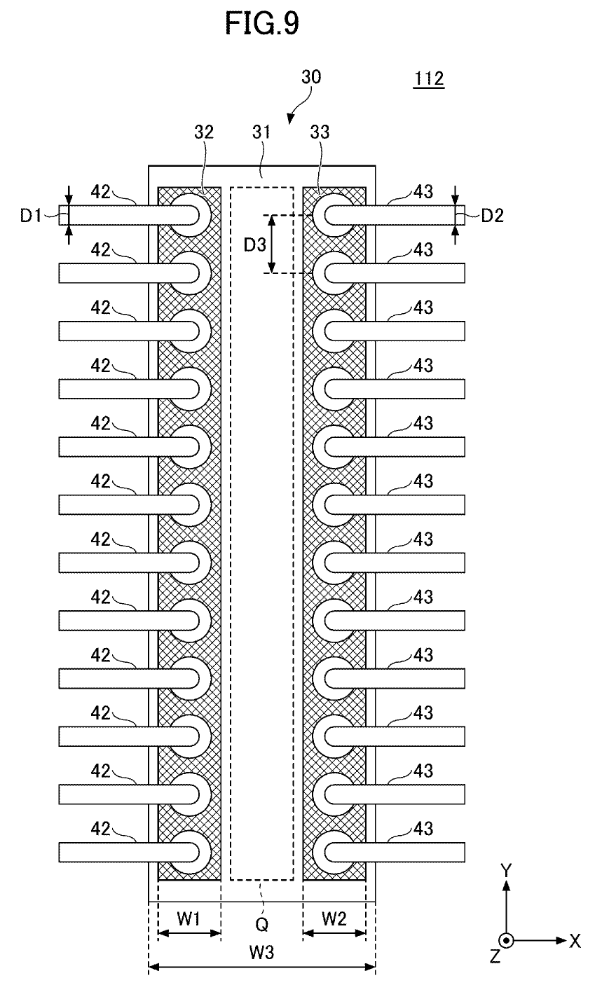

FIG. 9 is a plan view around the semiconductor chip 30 of a semiconductor device 112 according to a second comparative embodiment. In the semiconductor device 112 of the second comparative embodiment, the diameter D1 of the bonding wire 42 and the diameter D2 of the bonding wire 43 are larger than those of the first comparative embodiment. As a result, even with the same output power, the electrical resistance in the bonding wire 43 is lower than that in the first comparative embodiment. For example, when the diameter D2 is doubled, the electrical resistance per unit length is reduced to 1/4. Although a skin effect occurs under the high-frequency signal, when the current flows on the surface of the bonding wire 43, the electrical resistance per unit length becomes 1/2 when the diameter D2 is doubled. Thus, when the diameter D2 is doubled, the electrical resistance is reduced to between 1/4 and 1/2, and a voltage drop per unit length and Joule heat accompanying the voltage drop are also reduced to between 1/4 and 1/2. When the diameter D2 is doubled, the thermal resistance is reduced to 1/4. Thus, compared to the first comparative embodiment, the second comparative embodiment can reduce the temperature rise of the bonding wire 43 and can prevent the fusing of the bonding wire 43. When the diameter D2 is increased, an interval D3 of the bonding wire 43 in the Y direction is increased. However, even when the diameter D2 is doubled, the interval D3 is doubled or less than doubled, and the current flowing through one bonding wire 43 is doubled or less than doubled, and the electrical resistance per unit length is reduced to between 1/4 and 1/2, and the thermal resistance is reduced to 1/4. From this, even when the increase in the interval D3 is taken into consideration, the temperature rise of the bonding wire 43 can be reduced in the second comparative embodiment.

However, when the bonding wires 42 and 43 are made thick, the width W1 of the input pad 32 in the X direction and the width W2 of the output pad 33 in the X direction become large. For example, when the diameters D1 and D2 are 50 μm, the widths W1 and W2 are 160 μm or more. Thus, the width W3 of the semiconductor chip 30 in the X direction is larger than that of the first comparative embodiment. The manufacturing process of the semiconductor chip 30 is complicated, and the manufacturing cost per area of the semiconductor chip 30 is high. Thus, the cost of the semiconductor device 112 increases.

### Description of First Embodiment

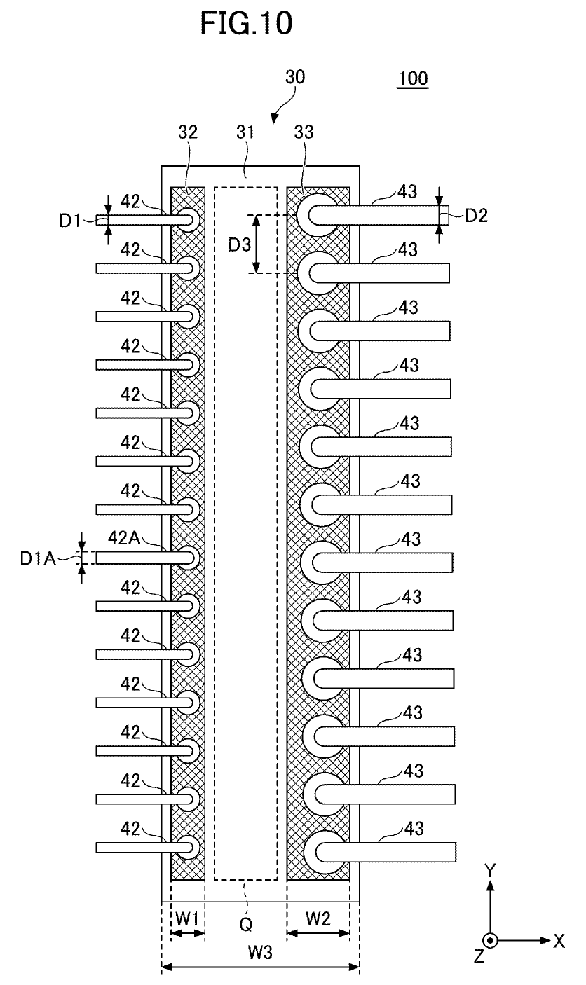

FIG. 10 is a plan view around the semiconductor chip 30 of the semiconductor device 100 according to the first embodiment. As illustrated in FIG. 10, in the semiconductor device 100 of the first embodiment, the diameter D1 of the bonding wire 42 is smaller than the diameter D2 of the bonding wire 43. When the diameter D1 of the bonding wire 42 is reduced, the inductance and resistance of the source S increase, and thus the gain is slightly reduced, but the reduction in the gain is limited. The efficiency and the maximum power hardly change even when the diameter D1 is reduced.

By making the bonding wire 43 thicker, the temperature rise of the bonding wire 43 can be reduced compared to the first comparative embodiment, and the bonding wire 43 can be prevented from being fused. By making the bonding wire 42 thinner, the width W1 of the input pad 32 in the X direction can be made smaller than the width W2 of the output pad 33 in the X direction, and the width W3 of the semiconductor chip 30 in the X direction can be made smaller than that of the second comparative embodiment. Thus, the cost of the semiconductor device 100 can be reduced.

The diameters D1 of the bonding wires 42 are the same as each other, but the diameter D1 may vary unintentionally. In addition, the diameter D1 may be intentionally changed. The diameters D2 of the bonding wires 43 are the same as each other, but the diameters D2 may vary unintentionally. In addition, the diameter D2 may be intentionally changed. In such a case, the diameter of the thickest bonding wire 42A among the bonding wires 42 is set to D1A. In the semiconductor device 100 of the first embodiment, the diameters D2 of all the bonding wires 43 are larger than the diameter D1A.

### First Modification of First Embodiment

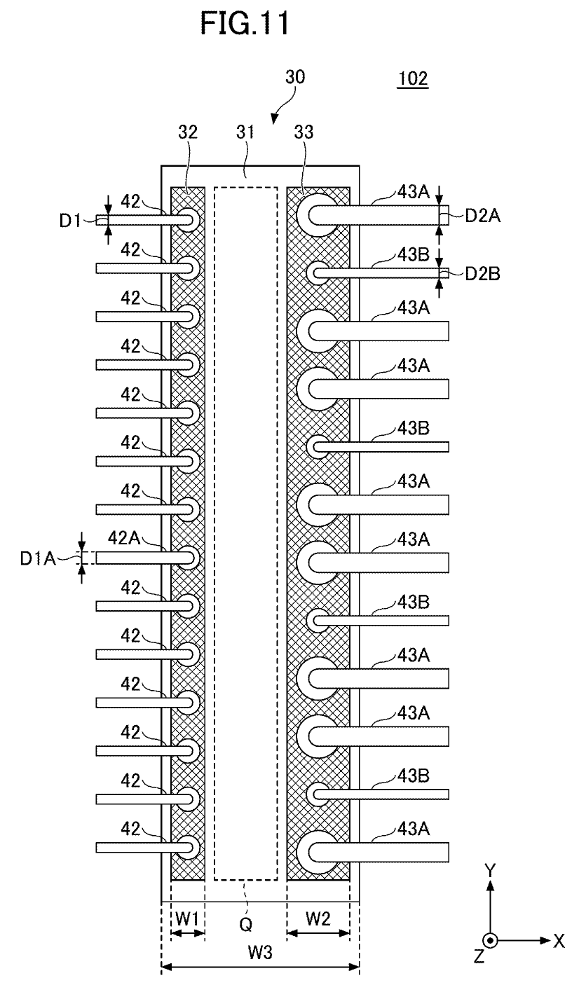

FIG. 11 is a plan view around the semiconductor chip 30 of a semiconductor device 102 according to a first modification of the first embodiment. As illustrated in FIG. 11, in the semiconductor device 102 of the first modification of the first embodiment, bonding wires 43A and 43B are bonded to the output pad 33. A diameter D2A of the bonding wire 43A is larger than a diameter D2B of the bonding wire 43B. The diameter D2A is larger than the diameter D1A. The diameter D2B may be the same as the diameter D1A, may be smaller than diameter D1A, or may be larger than the diameter D1A. The other configurations are the same as those of the semiconductor device 100 of the first embodiment, and the description thereof will be omitted.

### Second Modification of First Embodiment

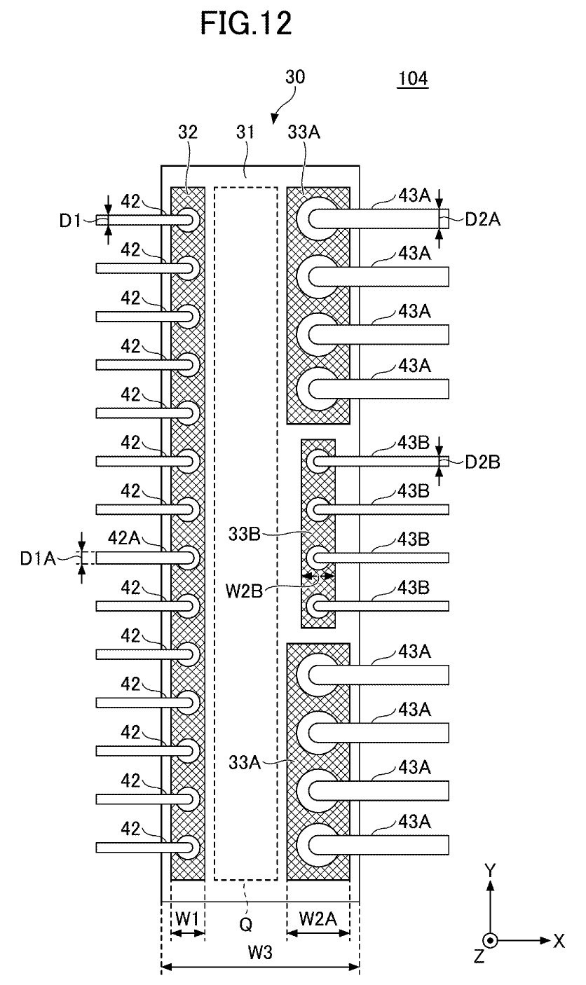

FIG. 12 is a plan view around the semiconductor chip 30 of a semiconductor device 104 according to a second modification of the first embodiment. As illustrated in FIG. 12, the semiconductor device 104 of the second modification of the first embodiment is provided with output pads 33A and 33B. The bonding wire 43A is bonded to the output pad 33A. The bonding wire 43B is bonded to the output pad 33B. A width W2B of the output pad 33B in the X direction is smaller than a width W2A of the output pad 33A in the X direction. The width W2B may be the same as the width W1, may be smaller than the width W1, or may be larger than the width W1. The other configurations are the same as those of the semiconductor device 102 of the first modification of the first embodiment, and the description thereof will be omitted.

According to the first embodiment and its modification, as illustrated in FIGS. 11 and 12, the bonding wire 42A (first input bonding wire) is the thickest among the bonding wires 42 (input bonding wires). The bonding wire 43A (first output bonding wire) is thicker than the bonding wire 42A, among the bonding wire 43A and the bonding wire 43B (output bonding wires). In this manner, as compared with the first comparative embodiment, by providing the thick bonding wire 43A, it is possible to reduce the fusing of the bonding wire 43A.

Further, as illustrated in FIGS. 11 and 12, the width W2 (or W2A) of the output pad 33 (or 33A) to which at least one of the bonding wires 43A is bonded is larger than the width W1 of the input pad 32. As a result, the width W1 of the input pad 32 can be reduced as compared with the second comparative embodiment, and thus the size of the semiconductor chip 30 can be reduced.

When the width of the input pad 32 in the X direction is different in the Y direction, the width W1 is the largest width of the input pad 32 in regions to which the bonding wires 42 are bonded. When the width of the output pad 33 in the X direction is different in the Y direction, the width W2 (or W2A) is the width of the output pad 33 or 33A in the X direction in a region (corresponding to the region 47A in FIG. 4) to which at least one of the bonding wires 43A is bonded.

The number of bonding wires 42 may be one or more. When the thickness of the bonding wires 42 is the same, the thickest bonding wire 42A among the bonding wires 42 corresponds to all the bonding wires 42. The bonding wire 42A may be one of the plurality of bonding wires 42, or may be the plurality of bonding wires 42.

The number of bonding wires 43 may be one or more. Only at least one of the bonding wires 43 (or 43A and 43B) needs to be thicker than the bonding wire 42A. From the viewpoint of increasing the number of bonding wires 43A to prevent fusing, the number of bonding wires 43A may be more than half of the total number of bonding wires 43A and 43B, may be 7/10 or more, and may be 9/10 or more.

From the viewpoint of preventing the bonding wire 43 or 43A from being fused, the diameter D2 of the bonding wire 43 or the diameter D2A of the bonding wire 43A may be 1.1 times or more, 1.2 times or more, or 1.5 times or more the diameter D1. From the viewpoint of reducing the size of the semiconductor chip 30, the width W2 or W2A may be 1.1 times or more, 1.2 times or more, or 1.5 times or more the width W1.

As in FIG. 10, all of the bonding wires 43 are thicker than the bonding wires 42A. This prevents all the bonding wires 43 from being fused.

As illustrated in FIGS. 10 to 12, in all regions to which the bonding wires 43A are bonded, the width W2 of the output pad 33 or the width W2A of the output pad 33A is larger than the width W1. This allows the size of the semiconductor chip 30 to be further reduced.

In FIGS. 2 and 3, the passive components 35A or 35B need not be provided. A second end of the bonding wire 42 may be bonded to the input terminal 24A. A second end of the bonding wire 43 may be bonded to the output terminal 24B.

A first end of the bonding wire 44 (second output bonding wire) is bonded to the electrode 37B of the passive component 35B (first passive component), and a second end of the bonding wire 44 is bonded to the output terminal 24B. At least one of the bonding wires 44 may be thicker than the bonding wire 42A. This prevents the bonding wire 44 from being fused.

From the viewpoint of preventing the bonding wires 44 from being fused, the number of bonding wires 44 thicker than the bonding wire 42A among the bonding wires 44 may be more than half of the total number of bonding wires 44. All of the bonding wires 44 may be thicker than bonding wire 42A.

A first end of the bonding wire 41 (second input bonding wire) is bonded to the electrode 37A of the passive component 35A (second passive component), and a second end of the bonding wire 41 is bonded to the input terminal 24A. The bonding wire 43A is thicker than the thickest bonding wire 41 among the bonding wires 41. This prevents the bonding wire 43 from being fused.

Some of the bonding wires 43 bonded to the output pad 33 may be shunt-connected to an output path electrically connecting the output pad 33 and the output terminal 24B. The current flowing through a shunt path is smaller than the current flowing through the output path. Thus, at least one of the bonding wires 43A is provided in the output path. This prevents the bonding wire 43A provided in the output path from being fused.

All of the bonding wires 43 provided in the output path are thicker than the bonding wire 42A. This prevents the bonding wire 43 provided in the output path from being fused.

The bonding wire 44 is connected in series with the bonding wire 43A in the output path. In such a case, at least one of the bonding wires 44 is made thicker than the bonding wire 42A. This prevents the bonding wire 44 provided in the output path from being fused.

As illustrated in FIGS. 5 to 7, the input pad 32 is a portion of the metal layer 16 connected to the gate electrode 13 (input electrode), which is located outside the active region 11 of the transistor Q and exposed from the protective film 18 covering the transistor Q. The output pad 33 is a portion of the metal layer 17 connected to the drain electrode 14 (output electrode), which is located outside the active region 11 and exposed from the protective film 18. This allows the size of the semiconductor chip 30 to be further reduced.

As illustrated in FIG. 4, the semiconductor chip 30 has a first side and a second side opposite to each other. The plurality of regions 46A where the plurality of bonding wires 42 are bonded to the input pad 32 are provided along the first side of the semiconductor chip 30. The plurality of regions 47A where the plurality of bonding wires 43 are bonded to the output pad 33 are provided along the second side. In such a structure, a large current flows through the bonding wire 43. Thus, by making the bonding wire 43 thicker than the bonding wire 42A, the bonding wire 43 can be prevented from being fused. The width W1 of the input pad 32 is the width of the input pad 32 in the direction perpendicular to the first side (i.e., the X direction). The width W2 of the output pad 33, the width W2A of the output pad 33A, and the width W2B of the output pad 33B are the widths of the output pads 33, 33A, and 33B respectively in the direction perpendicular to the second side (i.e., the X direction). This allows the size of the semiconductor chip 30 to be further reduced.

The thicknesses of the bonding wires 41 to 44 is the widths of the bonding wires 41 to 44 in a direction orthogonal to the extending direction of the bonding wires 41 to 44 when viewed from the Z direction, respectively. When the cross sections of the bonding wires 41 to 44 are circular, the thicknesses of the bonding wires 41 to 44 are the diameter of the cross sections of the bonding wires 41 to 44, respectively.

When the output power of the amplifier 50 is large, the bonding wires 43 and 44 are likely to be fused. Thus, when the maximum output power of the amplifier 50 is 5 W or more, 50 W or more, or 100 W or more, the inductors L1 and L2, and the capacitors C1 and C2, are provided.

The embodiments disclosed herein are to be considered in all respects as illustrative and not restrictive. The scope of the present disclosure is defined by the appended claims rather than by the foregoing description, and all changes that come within the meaning and range of equivalency of the claims are intended to be embraced therein.

What is claimed is:

1. A semiconductor device comprising:
a semiconductor chip including an amplifier, an input pad of the amplifier provided on an upper surface of the semiconductor chip, and an output pad of the amplifier provided on the upper surface of the semiconductor chip;
input bonding wires each having a first end bonded to the input pad; and
output bonding wires each having a first end bonded to the output pad,
wherein the input bonding wires include a first input bonding wire that is the thickest among the input bonding wires, and
wherein a width of the output pad in a region to which at least one of first output bonding wires among the output bonding wires is bonded is larger than a largest width of the input pad in regions to which the input bonding wires are bonded, the first output bonding wires being thicker than the first input bonding wire.

2. The semiconductor device according to claim 1,
wherein the number of the first output bonding wires is more than half of the number of the output bonding wires.

3. The semiconductor device of claim 1,
wherein all of the output bonding wires are thicker than the first input bonding wire.

4. The semiconductor device according to claim 1,
wherein, in all regions to which the first output bonding wires are bonded, the width of the output pad is larger than the largest width.

5. The semiconductor device according to claim 1, further comprising:
an output terminal electrically connected to the output pad,
wherein the at least one of the first output bonding wires is provided in an output path electrically connecting the output pad to the output terminal.

6. The semiconductor device according to claim 5,
wherein all of the output bonding wires provided in the output path are thicker than the first input bonding wire.

7. The semiconductor device according to claim 5, further comprising:
second output bonding wires connected in series with the at least one of the first output bonding wires in the output path,
wherein at least one of the second output bonding wires is thicker than the first input bonding wire.

8. The semiconductor device of claim 7, further comprising:
a base on which the semiconductor chip is mounted; and
a first passive component mounted on the base,
wherein the first output bonding wires each have a second end bonded to the first passive component, and
wherein the second output bonding wires each have a first end bonded to the first passive component and a second end bonded to the output terminal.

9. The semiconductor device according to claim 1, further comprising:
a base on which the semiconductor chip is mounted;
a second passive component mounted on the base;
an input terminal electrically connected to the input pad; and
second input bonding wires each having a first end bonded to the second passive component and a second end bonded to the input terminal,
wherein the first input bonding wire has a second end bonded to the second passive component, and
wherein at least one of the output bonding wires is thicker than any of the second input bonding wires.

10. The semiconductor device according to claim 1,
wherein the amplifier includes a transistor having an input electrode and an output electrode,
wherein the input pad is a portion of a metal layer electrically connected to the input electrode, and the portion is located outside an active region of the transistor and exposed from a protective film covering the transistor, and
wherein the output pad is a portion of a metal layer electrically connected to the output electrode, and the portion is located outside the active region and exposed from the protective film.

11. The semiconductor device according to claim 1,
wherein the upper surface of the semiconductor chip has a first side and a second side opposite to each other,
wherein a plurality of regions where the input bonding wires are bonded to the input pad are provided along the first side,
wherein a plurality of regions where the output bonding wires are bonded to the output pad are provided along the second side,
wherein the largest width is a largest width of the input pad in a direction perpendicular to an extending direction of the first side, and
wherein the width of the output pad is a width of the output pad in a direction perpendicular to an extending direction of the second side.
